(19) United States
(12) Patent Application Publication
(10) Pub. No.: US 2012/0181789 A1
(43) Pub. Date: Jul. 19, 2012

(54) Method And Systems For Detecting Electrical Discharges In A Machine

(76) Inventors: Charles Terrance Hatch, Gardnerville, NV (US); Adam Weiss, Minden, NV (US)

(21) Appl. No.: 13/009,462

(22) Filed: Jan. 19, 2011

(51) Int. Cl. H02P 9/04; G01R 31/00; H02P 9/02; G06F 19/00

(52) U.S. Cl. 290/44; 702/58; 322/99

(57) ABSTRACT

A monitoring system for use in detecting an electrical discharge within at least one component of a machine includes at least one sensor coupled to the machine for measuring an operating condition of the at least one component. The monitoring system includes a signal analysis module configured to receive a signal representative of the measured operating condition and to calculate an asymmetry value based on the signal received. The monitoring system includes a detection module coupled to the signal analysis module for detecting an electrical discharge within the at least one component based on the asymmetry value.

### BACKGROUND OF THE INVENTION

The present application relates generally to power generation systems and, more particularly, to a method and systems for use in detecting electrical discharges in a machine.

At least some known power generation systems, such as wind turbines, include a generator that supplies electrical power to an electrical grid or to another power distribution system. Such generators are driven by a rotating drive shaft that is supported by bearings. The bearings may be housed within a gearbox and/or within the generator. In at least some known generators, because of problems with grounding brushes, electrostatic discharge (ESD) may undesirably occur in the generator bearings. ESD may damage the bearing races and/or rolling elements. Further, exposure to ESD may cause one or more bearings to prematurely fail. Moreover, electrical noise caused by ESD may also produce an asymmetric noise component on sensor signals and generate false alarms in at least some known condition-based monitoring (CBM) systems coupled to the generator.

Known vibration monitoring techniques do not detect such ESD within generator bearings. Rather, separate sensors and/or monitoring equipment is required to detect ESD within a generator. Such sensors and monitoring equipment may be expensive, and may increase a cost of electricity generated by the power generation system.

### BRIEF DESCRIPTION OF THE INVENTION

In one embodiment, a monitoring system for use in detecting an electrical discharge within at least one component of a machine is provided that includes at least one sensor coupled to the machine for measuring an operating condition of the at least one component. The monitoring system includes a signal analysis module configured to receive a signal representative of the measured operating condition and to calculate an asymmetry value based on the signal received. The monitoring system includes a detection module that is coupled to the signal analysis module for detecting an electrical discharge within the at least one component based on the asymmetry value.

In another embodiment, a power generation system is provided that includes a machine and a monitoring system that is coupled to the machine. The monitoring system includes at least one sensor for measuring an operating condition of at least one component of the machine. The monitoring system also includes a signal analysis module and a detection module. The signal analysis module is configured to receive a signal representative of the measured operating condition and to calculate an asymmetry value based on the signal received. The detection module is coupled to the signal analysis module for detecting an electrical discharge based on the asymmetry value.

In yet another embodiment, a method for detecting an electrical discharge in a power generation system that includes a machine is provided. The method includes measuring an operating condition of at least one component of the machine, receiving a signal representative of the measured operating condition, calculating an asymmetry value based on the signal received, and detecting an electrical discharge based on the asymmetry value.

### BRIEF DESCRIPTION OF THE DRAWINGS

FIG. 1 is a block diagram of an exemplary power generation system.

FIG. 2 is a block diagram of an exemplary monitoring system that may be used with the power generation system shown in FIG. 1.

FIG. 3 is a flow diagram of an exemplary method for detecting electrical discharges that may be used with the monitoring system shown in FIG. 2.

### DETAILED DESCRIPTION OF THE INVENTION

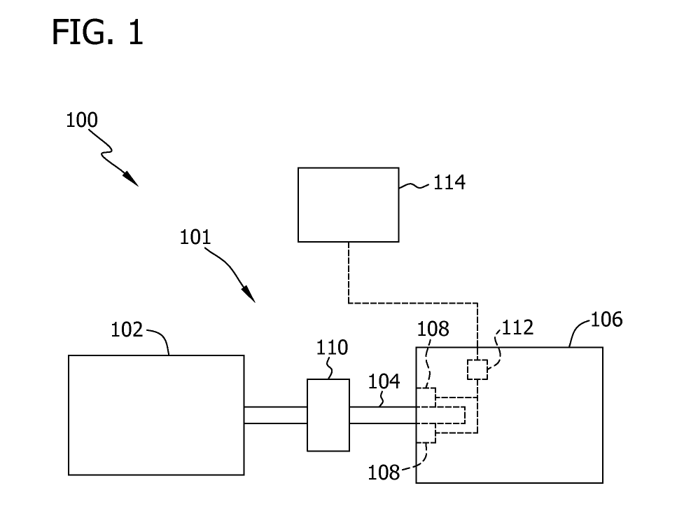

FIG. 1 shows an exemplary power generation system 100 that includes a machine 101. In the exemplary embodiment, machine 101 is a variable speed machine, such as a wind turbine, a hydroelectric turbine, gas turbine, and/or any other machine that operates with a variable speed. Alternatively, machine 101 may be a synchronous speed machine. In the exemplary embodiment, machine 101 includes a rotating device 102, such as a rotor or other device. Moreover, in the exemplary embodiment, rotating device 102 rotates a drive shaft 104 that is coupled to a generator 106. In the exemplary embodiment, generator 106 is a doubly-fed induction generator that is coupled to a power distribution system (not shown). Alternatively, generator 106 may be any other type of generator that is coupled to any electrical system that enables power generation system 100 to function as described herein. Drive shaft 104 is at least partially supported by one or more bearings 108 housed within generator 106. Alternatively or additionally, bearings 108 may be housed within a separate support structure 110, such as a gearbox, or within any suitable structure that enables power generation system 100 to operate as described herein.

In the exemplary embodiment, power generation system 100 includes at least one sensor 112 that detects and/or measures an operating condition of rotating device 102, drive shaft 104, generator 106, and/or any other component of power generation system 100 that enables system 100 to function as described herein. More specifically, in the exemplary embodiment, sensor 112 is an accelerometer that is positioned within generator 106 to measure vibrations induced to bearings 108, generator 106 and/or drive shaft 104. Alternatively, sensor 112 may be any other sensor or transducer that enables power generation system 100 to function as described herein. In the exemplary embodiment, sensor 112 transmits a signal representative of the measured operating condition (hereinafter referred to as a “sensor signal”) to a monitoring system 114 for processing and/or analysis. The sensor signal may include a plurality of components, such as, without limitation, one or more shaft vibration components and/or one or more noise components. Such noise components may result from one or more electrical discharges, such as an electro-static discharge (ESD) within at least one component of power generation system 100. For example, ESD may occur within generator 106, support structure 110, bearings 108, and/or drive shaft 104. In the exemplary embodiment, monitoring system 114 measures an asymmetry value of the sensor signal noise components to detect electrical discharges within power generation system 100.

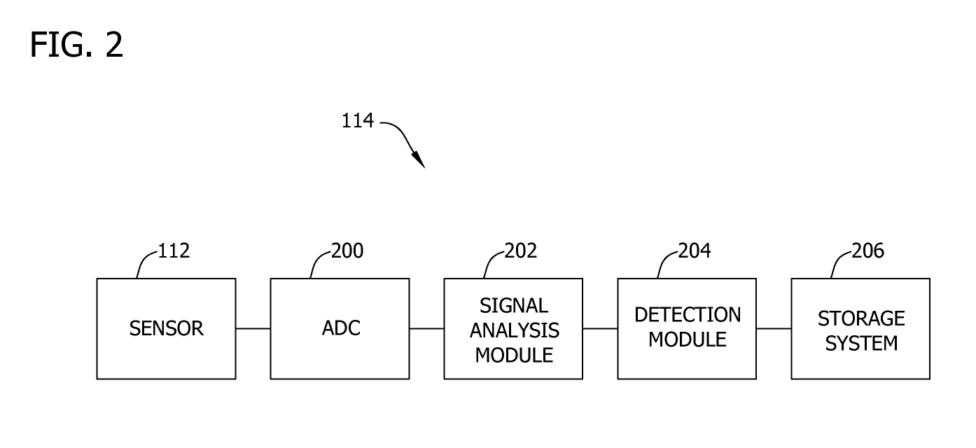

FIG. 2 is a block diagram of monitoring system 114. In the exemplary embodiment, monitoring system 114 includes sensor 112, an analog-to-digital converter (ADC) 200, a signal analysis module 202, a detection module 204, and a storage system 206. Moreover, in the exemplary embodiment, at least one component of monitoring system 114, such as signal analysis module 202, detection module 204, and/or any other component is stored within a computer readable medium (not shown) and/or is executed by a processor (not shown). As described more fully herein, in the exemplary embodiment, monitoring system 114 measures a statistical asymmetry value of a sensor signal, such as a signal transmitted by sensor 112 (shown in FIG. 1) and detects electrical discharges within power generation system 100 (shown in FIG. 1) using the measured asymmetry value.

As used herein, the computer readable medium may include, but is not limited to only including, random access memory (RAM), flash memory, a hard disk drive, a solid state drive, a diskette, a flash drive, a compact disc, a digital video disc, and/or any other non-transitory storage medium that enables monitoring system 114 to function as described herein. As used herein, the term “processor” includes any suitable programmable system including one or more systems and microcontrollers, microprocessors, reduced instruction set circuits (RISC), application specific integrated circuits (ASIC), programmable logic circuits (PLC), field programmable gate arrays (FPGA), and any other circuit capable of executing the functions described herein. The above examples are exemplary only, and thus are not intended to limit in any way the definition and/or meaning of the term “processor.”

In the exemplary embodiment, sensor 112 measures at least one operating condition of power generation system 100 and transmits an analog sensor signal representative of the measured operating condition to ADC 200. Alternatively, sensor 112 may be fabricated unitarily with ADC 200 such that sensor 112 transmits a digital sensor signal representative of the measured operating condition to signal analysis module 202, rather than to ADC 200.

Electrical noise may be generated within power generation system 100. For example, a faulty grounding circuit and/or a faulty grounding mechanism may cause noise to be generated and/or distributed throughout portions of power generation system 100. In the exemplary embodiment, at least a portion of the electrical noise within power generation system 100 is received by sensor 112 and is transmitted to ADC 200 as a component of the sensor signal. ADC 200, in the exemplary embodiment, receives the sensor signal from sensor 112 and converts the sensor signal from an analog signal to a digital signal. ADC 200 transmits the digital sensor signal to signal analysis module 202.

Signal analysis module 202, in the exemplary embodiment, measures an asymmetry value of the sensor signal. More specifically, in the exemplary embodiment, signal analysis module 202 stores values representative of the digital sensor signal (hereinafter referred to as “sensor values”) in a memory (not shown). After signal analysis module 202 has stored a predetermined number of sensor values, module 202 compiles the values into a statistical distribution. Signal analysis module 202 then calculates an asymmetry value of the statistical distribution of the sensor values. More specifically, in the exemplary embodiment, signal analysis module 202 calculates a skewness value (also known as a normalized third central moment) of the sensor values. The skewness value represents a statistical level of asymmetry of the distribution of sensor values, and thus, represents a level of asymmetry of the sensor signal. Moreover, the level of asymmetry of the sensor signal, i.e., a magnitude of the skewness value, is indicative of an amount of asymmetric noise associated with electrical discharges, such as electrostatic discharges (ESD) within power generation system 100. The polarity of the skewness value indicates a polarity of electrical discharges within power generation system 100. For example, a negative skewness value indicates that the electrical discharges have a generally negative polarity, and a positive skewness value indicates that the electrical discharges have a generally positive polarity. Signal analysis module 202 transmits the sensor values and/or a signal representative of the calculated skewness value to detection module 204.

In an alternative embodiment, signal analysis module 202 calculates an asymmetry value of the sensor signal using a different algorithm than a skewness calculation algorithm. In one embodiment, signal analysis module 202 calculates a minimum value, a maximum value, and a mean value of the sensor values. In such an embodiment, signal analysis module 202 may calculate an asymmetry value of the sensor values using the following equation:

|(minimum value−mean value)|−|(maximum value−mean value)| Eq. 1

If the result of Eq. 1 is non-zero, then signal analysis module 202 may determine that the sensor values are asymmetric. Moreover, signal analysis module 202 may determine that the asymmetry of the sensor values is proportional to the magnitude of the result of Eq. 1. In such an embodiment, signal analysis module 202 transmits the sensor values and/or a signal representative of the result of Eq. 1 to detection module 204.

In the exemplary embodiment, detection module 204 receives the signal transmitted by signal analysis module 202 and determines if at least one error condition is satisfied. More specifically, in the exemplary embodiment, an error condition is satisfied if an absolute value of the asymmetry value is greater than a predetermined threshold. For example, an error condition may be satisfied if a magnitude of the skewness value is greater than one. Alternatively, an error condition may be satisfied if a magnitude of the skewness value and/or the asymmetry value exceeds any suitable value that enables monitoring system 114 to function as described herein. If an error condition is satisfied, detection module 204 transmits an error signal to a suitable system, such as to storage system 206. Moreover, in the exemplary embodiment, detection module 204 transmits the sensor values to storage system 206. Alternatively, any other error notification may be generated by detection module 204 and/or transmitted to any system that enables monitoring system 114 to function as described herein.

Storage system 206, in the exemplary embodiment, receives the sensor values, the asymmetry value, and/or the error signal and stores the values of the signals in a memory (not shown). In the exemplary embodiment, the memory includes a computer readable medium, such as, without limitation, random access memory (RAM), flash memory, a hard disk drive, a solid state drive, a diskette, a flash drive, a compact disc, a digital video disc, and/or any suitable memory that enables storage system 206 to store, retrieve, and/or execute instructions and/or data. Moreover, in the exemplary embodiment, storage system 206 is a server, such as a power plant server or a wind farm server that is positioned remotely from the other components of power generation system 100. Alternatively, storage system 206 may be any system and/or is positioned in any location that enables power generation system 100 to function as described herein. Moreover, in the exemplary embodiment, storage system 206 includes a display (not shown) that displays a graphical and/or a textual representation of the sensor values to a user.

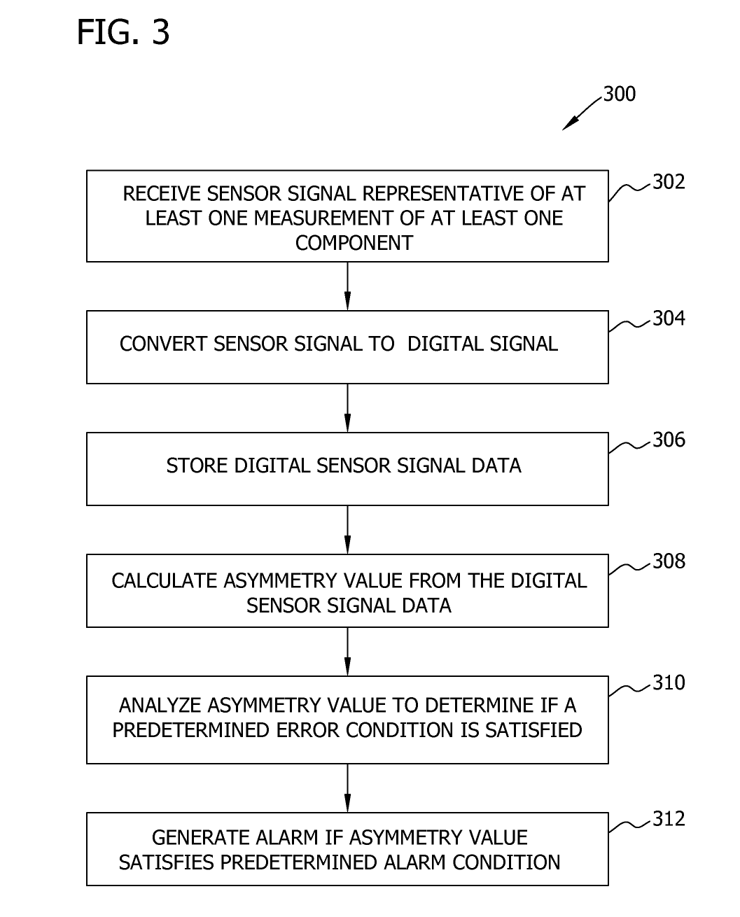

FIG. 3 is a flow diagram 300 illustrating an exemplary method of detecting an electrical discharge that may be used with monitoring system 114 (shown in FIG. 2) and/or with power generation system 100 (shown in FIG. 1). In the exemplary embodiment, the method is embodied within a computer readable medium (not shown) and/or is executed by a processor (not shown).

In the exemplary embodiment, a sensor signal is received 302 that is representative of at least one measurement of at least one component of a power generation system, such as power generation system 100. For example, a signal representative of an acceleration of drive shaft 104 may be received 302 from sensor 112 (both shown in FIG. 1). Alternatively, a signal representative of a measurement of any component may be received 302 from any sensor that enables the method to function as described herein. The sensor signal is then converted 304 to a digital sensor signal by ADC 200 (shown in FIG. 2) and/or by any other conversion device.

In the exemplary embodiment, data representative of the digital sensor signal is stored 306 in a memory, such as in a computer readable medium described above with reference to FIG. 2. More specifically, a predetermined amount of digital sensor signal data, such as an amount of data associated with one revolution of drive shaft 104, is stored 306 within the memory. An asymmetry value, such as a skewness value, is calculated 308 from the predetermined amount of digital sensor signal data. Alternatively, any other measurement of asymmetry may be calculated 308 that enables the method to function as described herein.

The asymmetry value, in the exemplary embodiment, is then analyzed 310 to determine if a predetermined error condition is satisfied. More specifically, in the exemplary embodiment, during execution of the method, a determination 310 is made that an error condition is satisfied if an absolute value of the asymmetry value is greater than a predetermined threshold. For example, an error condition may be satisfied if the magnitude of a skewness value of the digital sensor signal data is greater than one. Alternatively, an error condition may be satisfied if the magnitude of the skewness value and/or the asymmetric value exceeds any value that enables the method to function as described herein.

In the exemplary embodiment, if the error condition is satisfied, an alarm is generated 312. For example, an error signal and/or an error message may be transmitted to a remote system (not shown) and/or to storage system 206 (shown in FIG. 2) for use in notifying a user, an audible alarm and/or a visual alarm may be activated to alert a user, and/or any other alarm may be generated 312 that enables the method to function as described herein. After an alarm has been generated 312 or a user has otherwise been notified, the user may correct the error condition, for example, by replacing faulty grounding brushes (not shown) of generator 106, replacing damaged bearings 108, and/or by performing any other maintenance or repair on any other components of power generation system 100.

As described herein, monitoring system 114 and the method detect electrical discharges within power generation system 100. More specifically, in the exemplary embodiment, monitoring system 114 and the method detect electro-static discharges (ESD) within one or more components of power generation system 100, such as within generator 106, bearings 108, support structure 110, and/or drive shaft 104 of power generation system 100. Moreover, monitoring system 114 and the method detect ESD by calculating 308 an asymmetry value, such as a skewness value, of a noise component within a sensor signal, and analyzing 310 the asymmetry value by comparing the asymmetry value to a predetermined threshold value. Known wind turbines and other power generation systems generally are unable to detect such ESD using a sensor signal, and often filter out noise components from the sensor signal rather than attempting to analyze the noise signal for a presence of ESD.

A technical effect of the systems and method described herein includes at least one of: (a) measuring an operating condition of at least one component of a machine; (b) receiving a signal representative of a measured operating condition; (c) calculating an asymmetry value based on a sensor signal received; and (d) detecting an electrical discharge based on an asymmetry value of a sensor signal.

The above-described embodiments provide an efficient and cost-effective monitoring system and method for use in detecting electrical discharges within a power generation system. The monitoring system receives a sensor signal from a sensor and calculates an asymmetry value of the sensor signal and/or a noise component of the sensor signal. The asymmetry value is representative of an amount of electrical discharge within the power generation system. The monitoring system compares the asymmetry value with a predetermined threshold value to determine if an error has occurred and/or if an unacceptable amount of electrical discharge is present within the power generation system. If an error has occurred and/or if an unacceptable amount of electrical discharge is detected, the monitoring system may generate an alarm and/or notify a user. As such, the monitoring system and method described herein efficiently and cost-effectively detect electrical discharges within a power generation system.

Exemplary embodiments of methods and systems for use in detecting electrical discharges are described above in detail. The methods and systems are not limited to the specific embodiments described herein, but rather, components of the systems and/or steps of the methods may be utilized independently and separately from other components and/or steps described herein. For example, the monitoring system may also be used in combination with other power systems and methods, and is not limited to practice with only the power generation system as described herein. Rather, the exemplary embodiment can be implemented and utilized in connection with many other power system applications.

Although specific features of various embodiments of the invention may be shown in some drawings and not in others, this is for convenience only. In accordance with the principles of the invention, any feature of a drawing may be referenced and/or claimed in combination with any feature of any other drawing.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

What is claimed is:

1. A monitoring system for use in detecting an electrical discharge within at least one component of a machine, said monitoring system comprising:
at least one sensor coupled to the machine for measuring an operating condition of the at least one component;
a signal analysis module configured to:
receive a signal representative of the measured operating condition; and
calculate an asymmetry value based on the signal received; and
a detection module coupled to said signal analysis module for detecting an electrical discharge within the at least one component based on the asymmetry value.

2. A monitoring system in accordance with claim 1, further comprising an analog-to-digital converter coupled to said at least one sensor, said analog-to-digital converter configured to convert a signal received from said at least one sensor to a digital signal.

3. A monitoring system in accordance with claim 1, wherein said at least one sensor comprises an accelerometer.

4. A monitoring system in accordance with claim 1, wherein said at least one sensor is within a wind turbine for use in measuring an amount of vibration induced to the wind turbine.

5. A monitoring system in accordance with claim 1, wherein said signal analysis module is configured to calculate a skewness value based on the signal received.

6. A monitoring system in accordance with claim 5, wherein said detection module is configured to compare the skewness value to a predetermined threshold value to detect an electrical discharge.

7. A monitoring system in accordance with claim 6, wherein said detection module is configured to generate an error signal if the skewness value is greater than the predetermined threshold value.

8. A power generation system comprising:
a machine; and
a monitoring system coupled to said machine and comprising:
at least one sensor for measuring an operating condition of at least one component of said machine;
a signal analysis module configured to:
receive a signal representative of the measured operating condition; and
calculate an asymmetry value based on the signal received; and
a detection module coupled to said signal analysis module for detecting an electrical discharge based on the asymmetry value.

9. A power generation system in accordance with claim 8, further comprising an analog-to-digital converter coupled to said at least one sensor, said analog-to-digital converter configured to convert a signal received from said at least one sensor to a digital signal.

10. A power generation system in accordance with claim 8, wherein said at least one sensor comprises an accelerometer.

11. A power generation system in accordance with claim 8, wherein said at least one sensor is within a wind turbine for use in measuring an amount of vibration induced to the wind turbine.

12. A power generation system in accordance with claim 8, wherein said signal analysis module is configured to calculate a skewness value based on the signal received.

13. A power generation system in accordance with claim 12, wherein said detection module is configured to compare the skewness value to a predetermined threshold value to detect an electrical discharge.

14. A power generation system in accordance with claim 13, wherein said detection module is configured to generate an error signal if the skewness value is greater than the predetermined threshold value.

15. A method for detecting an electrical discharge in a power generation system that includes a machine, said method comprising:
measuring an operating condition of at least one component of the machine;
receiving a signal representative of the measured operating condition;
calculating an asymmetry value based on the signal received; and
detecting an electrical discharge based on the asymmetry value.

16. A method in accordance with claim 15, further comprising converting the signal received to a digital signal.

17. A method in accordance with claim 15, further comprising measuring an amount of vibration induced to the wind turbine using at least one sensor within a wind turbine.

18. A method in accordance with claim 15, wherein said calculating an asymmetry value based on the signal received comprises calculating a skewness value based on the signal received.

19. A method in accordance with claim 18, wherein said detecting an electrical discharge based on the asymmetry value comprises comparing the skewness value to a predetermined threshold value.

20. A method in accordance with claim 18, wherein said detecting an electrical discharge based on the asymmetry value further comprises generating an error signal if the skewness value is greater than the predetermined threshold value.
